(19) United States
(12) Patent Application Publication
(10) Pub. No.: US 2007/0293045 A1
(43) Pub. Date: Dec. 20, 2007

(54) Semiconductor device and method for fabricating the same

(75) Inventors: Ki-Seog Youn, Suwon-si (KR); Jong-Hyon Ahn, Suwon-si (KR); Joo-Hyoung Lee, Suwon-si (JP); Kwang-Duk Kim, Namdong-gu (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD

(21) Appl. No.: 11/808,981

(22) Filed: Jun. 14, 2007

(30) Foreign Application Priority Data
Jun. 16, 2006 (KR) 10-2006-0054473

(51) Int. Cl. H01L 21/302

(52) U.S. Cl. 438/689

(57) ABSTRACT

A semiconductor device may include a semiconductor substrate having a trench, a device isolation layer filling the trench, and a liner nitride layer disposed between the semiconductor substrate and the device isolation layer. The device isolation layer may additionally cover a portion of the substrate surrounding the trench. The liner nitride layer may have an upper portion and a lower portion, wherein the upper portion may be thinner than the lower portion. The liner nitride layer may reduce or prevent a recess from being generated between an active region and a device isolation region. Accordingly, a relatively high-quality semiconductor device may be fabricated using a simplified process.

### PRIORITY STATEMENT

This U.S. non-provisional patent application claims priority under 35 U.S.C. § 119 to Korean Patent Application No. 10-2006-0054473, filed on Jun. 16, 2006 in the Korean Intellectual Property Office (KIPO), the entire contents of which are incorporated herein by reference.

### BACKGROUND

1. Technical Field

Example embodiments relate to a semiconductor device and a method for fabricating the same.

2. Description of the Related Art

The miniaturization of semiconductor devices has being pursued for purposes of achieving higher integration and higher performance of semiconductor devices. Consequently, the pursuit of miniaturization has led to the fabrication of semiconductor devices having device isolation layers. A LOCOS (LOCal Oxidation of Silicon) process may be used to form such a device isolation layer. However, the LOCOS process may present problems involving size loss (e.g., “bird's beak” phenomenon). On the other hand, an STI (shallow trench isolation) process may be used to form a device isolation layer for isolating semiconductor devices from each other. In the STI process, a shallow trench formed in a semiconductor substrate may be filled with a gap-fill insulating layer to form the device isolation layer. A benefit of the STI process may be that it may be relatively free of the size loss problem that may occur in the LOCOS process.

However, the STI process may be more complex than the LOCOS process. In addition, the STI process may have problems of stress, recess, and trench gap fill. Stress may be caused by the difference between the thermal expansion coefficients of the semiconductor substrate and the gap-fill insulating layer filling the trench. Stress may also be caused by the cubical expansion of an inner wall of the trench during an oxidation process after the filling of the trench. The stress caused by cubical expansion may be more severe than the stress caused by the difference between the thermal expansion coefficients. Furthermore, because the area of the inner wall of the trench may increase with the miniaturization of the semiconductor device, the stress caused by the oxidation process may increase with the miniaturization of the semiconductor device, thus causing problems, including crystal defects and junction leakage.

To alleviate stress, a liner nitride layer may be formed on the inner wall of the trench. The liner nitride layer may be a thin silicon nitride (SiₓN_{y}) layer. The silicon nitride layer reduces or prevents the passage of materials (e.g., water (H₂O)) that may oxidize the semiconductor substrate. Deposition of the thin silicon nitride layer on the inner wall of the trench may prevent oxidation of the inner wall and may reduce or suppress the occurrence of stress during subsequent processing.

FIGS. 1A through 1H are sectional views illustrating a method for fabricating a conventional semiconductor device. Referring to FIGS. 1A through 1C, a pad oxide layer 12 and a pad nitride layer 14 may be formed on a semiconductor substrate 10. A photoresist pattern 16 may be formed on the pad nitride layer 14. The pad nitride layer 14 and the pad oxide layer 12 may be etched to form a mask pattern 17 (including a pad nitride layer pattern 14a and a pad oxide layer pattern 12a) having an opening that exposes a device isolation region of the semiconductor substrate 10.

The photoresist pattern 16 may be removed, and the mask pattern 17 may be used as an etch mask to etch the exposed device isolation region of the semiconductor substrate 10 to form a trench 18. Alternatively, the photoresist pattern 16 may be used as an etch mask to sequentially etch the pad nitride layer 14, the pad oxide layer 12, and the semiconductor substrate 10 to form a trench 18.

Referring to FIGS. 1D and 1E, a liner oxide layer 20 may be formed on an inner wall of the trench 18, and a liner nitride layer 22 may be formed on the semiconductor substrate 10 including the trench 18. Referring to FIGS. 1F through 1H, a gap-fill insulating layer 24 may be formed on the semiconductor substrate 10 including the interior of the trench 18. Using the mask pattern 17 as an etch stop layer, the gap-fill insulating layer 24 may be etched to form a device isolation layer 24a that fills the trench 18 and the opening of the mask pattern 17. The device isolation layer 24a may define an active region of the semiconductor substrate 10.

An etching process may be performed to remove the liner nitride layer 22 and a pad nitride layer pattern 14a that may be located at the upper portion of the active region defined by the device isolation layer 24a. However, this etching process may cause a recessed portion A (FIG. 1H) near the upper portion of the liner nitride layer 22. Additionally, the device isolation layer 24a may be subjected to subsequent cleaning/etching processes that may reduce the height of the device isolation layer 24a and further deepen the recessed portion A. Accordingly, the recessed portion A may cause, for example, current leakage at a gate insulating layer (not shown) or junction leakage during the forming of a salicide layer.

Additionally, the recessed portion A may cause the generation of a poly stringer when a polysilicon layer may be deposited during a subsequent gate electrode forming process. The poly stringer may cause a bridge between the gate electrodes (not shown) and may also affect the operational characteristics (e.g., the threshold voltage Vₜₕ) of a semiconductor device, thus obstructing the gate electrode forming process. Although a process of filling the recessed portion A with a silicon nitride layer (divot process) may be performed to reduce or prevent the above problems, a divot process may complicate the semiconductor device fabrication process.

### SUMMARY OF EXAMPLE EMBODIMENTS

Example embodiments relate to a semiconductor device that may reduce or prevent a recess from being generated between an active region and a device isolation region and a method for fabricating the same. A semiconductor device according to example embodiments may include a semiconductor substrate having a trench, a device isolation layer in the trench and on at least a portion of the surface of the semiconductor substrate surrounding the trench, and/or a liner nitride layer between the semiconductor substrate and the device isolation layer.

The liner nitride layer may have an upper portion and a lower portion, wherein the upper portion of the liner nitride layer may be thinner than the lower portion of the liner nitride layer. The upper portion of the liner nitride layer may be one-third as thick as the lower portion of the liner nitride layer. For example, the upper portion of the liner nitride layer may have a thickness of about 40˜50 Å. The upper portion of the liner nitride layer may also be spacer-shaped.

The device isolation layer may include a lower device isolation layer and an upper device isolation layer. The lower portion of the liner nitride layer may be between the lower device isolation layer and the semiconductor substrate, while the upper portion of the liner nitride layer may be between the upper device isolation layer and the semiconductor substrate. The upper device isolation layer may have an upper portion that may be wider than the trench. For example, the upper portion of the upper device isolation layer may be on a portion of the semiconductor substrate surrounding the trench.

Methods for fabricating a semiconductor device according to example embodiments may include providing a mask pattern on a semiconductor substrate, the mask pattern having an opening that exposes a region of the semiconductor substrate. The exposed region of the semiconductor substrate may be etched to form a trench. Additionally, a portion of the mask pattern surrounding the trench may be etched so as to form a mask pattern opening, the mask pattern opening exposing the surface of the substrate surrounding the trench. A liner nitride layer may be formed to cover the semiconductor substrate including the trench. The liner nitride layer may be etched such that the upper portion may be thinner than the lower portion. A device isolation layer may be formed to fill the trench and the mask pattern opening, and at least a portion of the mask pattern may be removed.

Forming the device isolation layer may include forming a lower device isolation layer in the trench such that the lower device isolation may have an upper surface lower than the surface of the semiconductor substrate and forming an upper device isolation layer on the lower device isolation layer so as to fill the trench and the mask pattern opening. Forming the lower device isolation layer may include forming a first gap-fill insulating layer so as to fill the trench and recessing the first gap-fill insulating layer to form the lower device isolation layer having an upper surface lower than the surface of the semiconductor substrate. Forming the lower device isolation layer may also expose the upper portion of the liner nitride layer.

Forming the upper device isolation layer may include etching the upper portion of the liner nitride layer exposed by the forming of the lower device isolation layer so as to thin the exposed upper portion of the liner nitride layer, forming a second gap-fill insulating layer on the lower device isolation layer so as to fill the trench and the mask pattern opening, and planarizing the second gap-fill insulating layer using the mask pattern as an etch stop layer so as to form the upper device isolation layer. The exposed upper portion of the liner nitride layer may be etched using a wet etching process or an anisotropic dry etching process.

Alternatively, forming the upper device isolation layer may include performing a plurality of cycles of a deposition/etch process on the lower device isolation layer to form a second gap-fill insulating layer covering the semiconductor substrate and filling the trench and the mask pattern opening, wherein the exposed upper portion of the liner nitride layer may be gradually thinned with the forming of the second gap-fill insulating layer. The second gap-fill insulating layer may be planarized using the mask pattern as an etch stop layer so as to form the upper device isolation layer.

### BRIEF DESCRIPTION OF THE DRAWINGS

FIGS. 1A through 1H are sectional views illustrating a method for fabricating a conventional semiconductor device.

FIGS. 2A through 2L are sectional views illustrating a method for fabricating a semiconductor device according to example embodiments.

FIGS. 3A through 3L are sectional views illustrating a method for fabricating a semiconductor device according to additional example embodiments.

### DETAILED DESCRIPTION OF EXAMPLE EMBODIMENTS

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

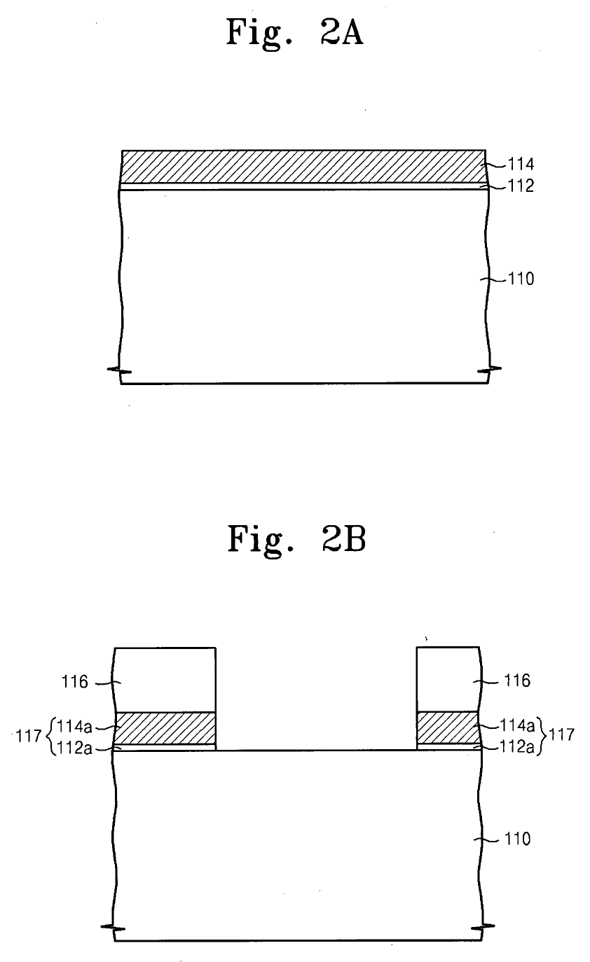

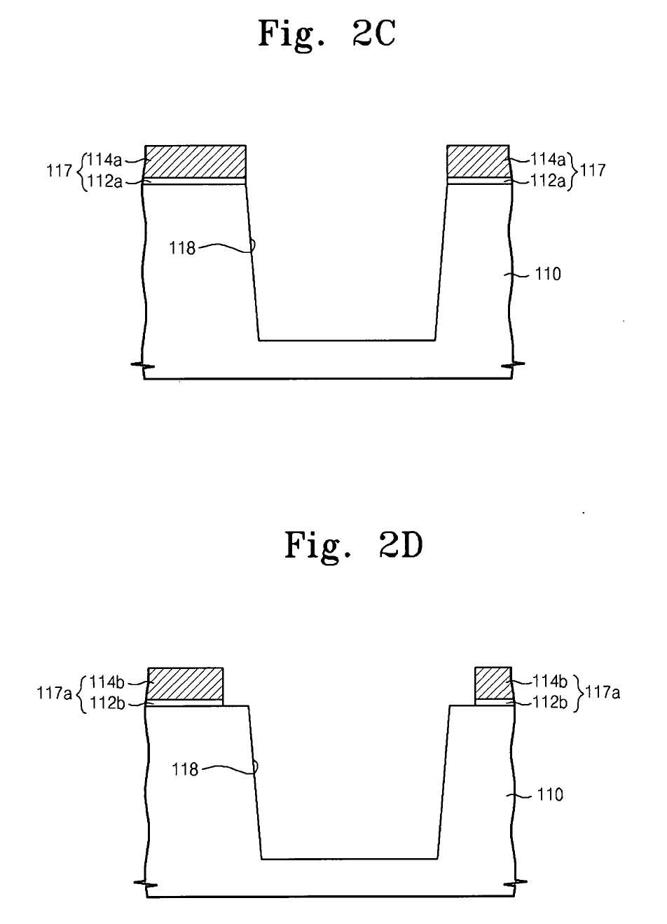

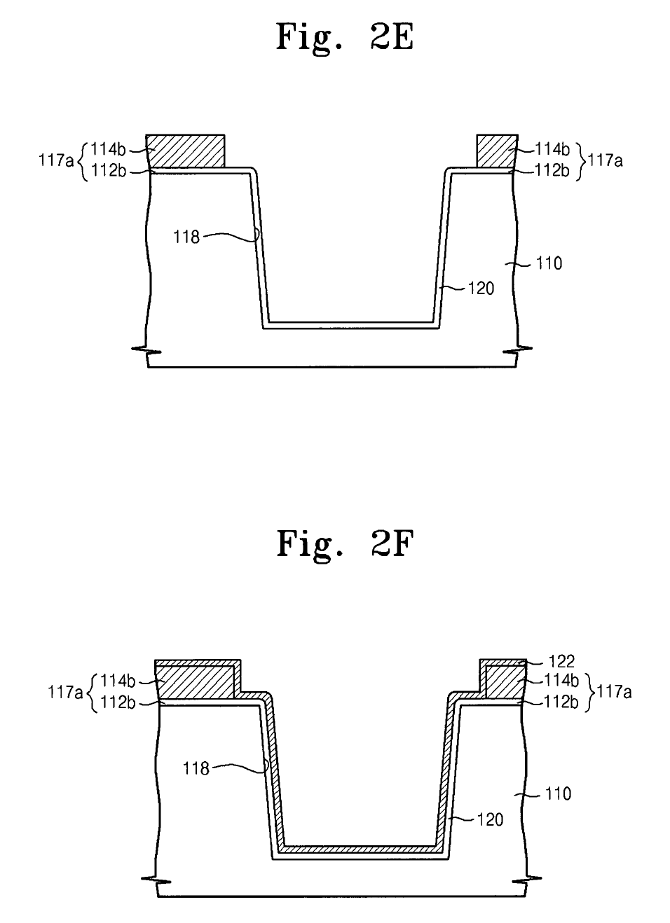

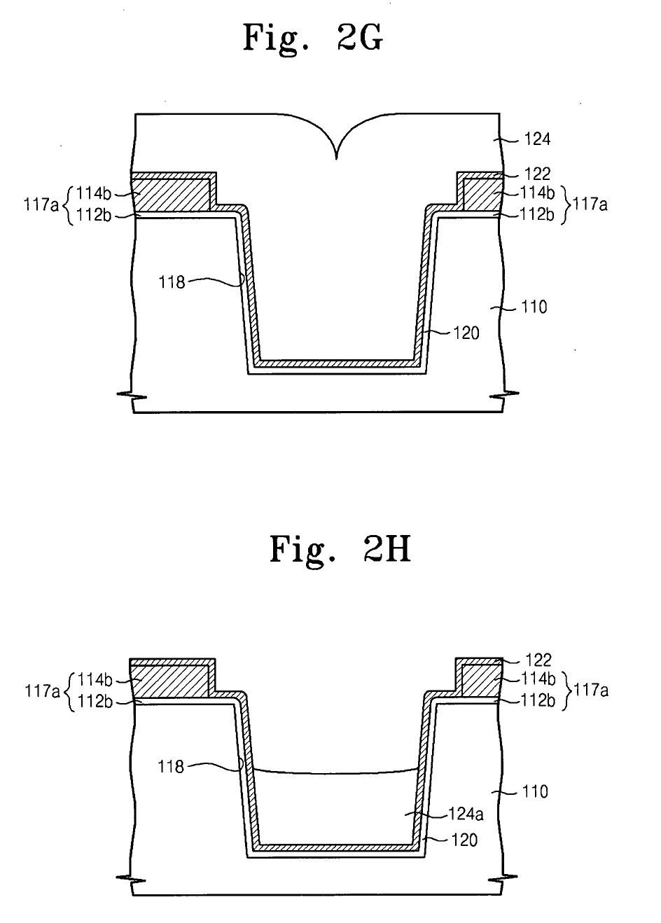

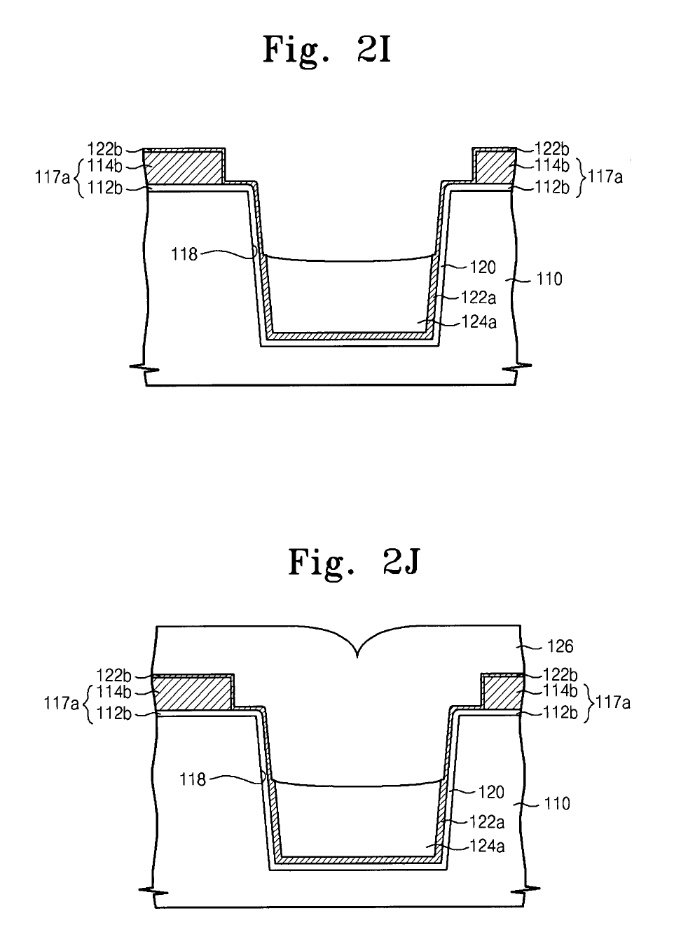

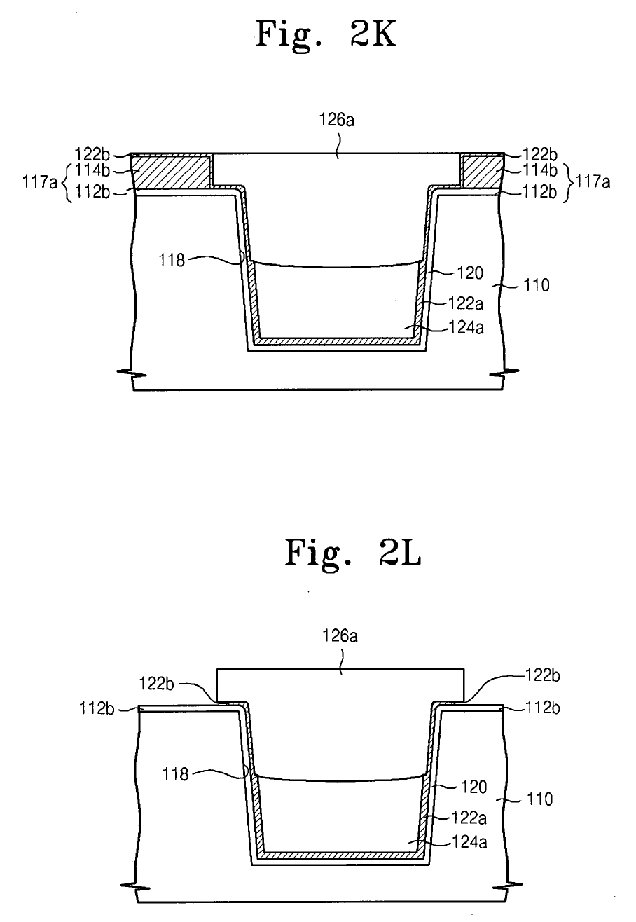

FIGS. 2A through 2L are sectional views illustrating a method for fabricating a semiconductor device according to example embodiments. Referring to FIG. 2A, a pad oxide layer 112 and a pad nitride layer 114 may be formed on a semiconductor substrate 110. The pad oxide layer 112 may be a silicon oxide layer formed by thermal oxidation. The pad oxide layer 112 may be formed to a thickness of about 40˜65 Å by thermally oxidizing the semiconductor substrate 110 at a temperature of about 800° C. The pad nitride layer 114 may be a silicon nitride layer formed by diffusion or by chemical vapor deposition (CVD). The pad nitride layer 114 may be formed to a thickness of about 800˜1500 Å at a temperature of about 760° C. The pad nitride layer 114 may be difficult to oxidize and, thus, may be used as a mask for preventing oxidation of the semiconductor substrate 110 thereunder. The pad oxide layer 112 may reduce the stress generated at the interface between the semiconductor substrate 110 and the pad nitride layer 114 and may reduce or prevent the generation of a stress-induced defect on the surface of the semiconductor substrate 110.

Referring to FIG. 2B, a photoresist pattern 116 may be provided on the pad nitride layer 114. Using the photoresist pattern 116 as an etch mask, the pad nitride layer 114 and the pad oxide layer 112 may be etched to form a trench mask pattern 117 (including a pad nitride layer pattern 114a and a pad oxide layer pattern 112a). The etching of the pad nitride layer 114 and the pad oxide layer 112 may be performed using dry etching.

Referring to FIG. 2C, the photoresist pattern 116 may be removed, and the trench mask pattern 117 may be used as an etch mask to etch the semiconductor substrate 110 for forming a trench 118. The trench 118 may be formed to a depth of about 3500˜4500 Å using anisotropic dry etching. Alternatively, the photoresist pattern 116 may be used as an etch mask to sequentially etch the pad nitride layer 114, the pad oxide layer 112, and the semiconductor substrate 110 to form the trench 118.

Referring to FIG. 2D, the portion of the trench mask pattern 117 surrounding the trench 118 may be etched to form a device isolation layer mask pattern 117a (including a pad nitride layer pattern 114b and a pad oxide layer pattern 112b) such that a mask pattern opening additionally exposes the surface of the semiconductor substrate 110 surrounding the trench 118. For example, the trench mask pattern 117 may be etched to about 300 Å from the edge of the trench 118. The etching of the portion of the trench mask pattern 117 surrounding the trench 118 may be performed using pull-back etching. Pull-back etching may be a dry etching process using plasma or a wet etching process using an etchant including phosphoric acid (H₃PO₄).

Referring to FIG. 2E, to remove etch damage from the inner wall of the trench 118, the inner wall of the trench 118 may be oxidized to form a thin silicon oxide layer (not shown) and wet-etching the inner wall of the trench 118 to remove the thin silicon oxide layer. A liner oxide layer 120 may be formed on the inner wall of the trench 118. The liner oxide layer 120 may be a silicon oxide layer formed by thermal oxidation or by rapid thermal oxidation (RTO). The liner oxide layer 120 may be formed to a thickness of about 100˜200 Å at a temperature of about 1000° C.

Referring to FIG. 2F, a liner nitride layer 122 may be formed on the semiconductor substrate 110 including the inner wall of the trench 118. The liner nitride layer 122 may be a silicon nitride layer formed by diffusion or CVD. The liner nitride layer 122 may be formed to a thickness of about 150˜200 ÅÅ at a temperature of about 760° C. The liner nitride layer 122 may reduce or prevent oxidation of the inner wall of the trench 118 and may reduce stress during subsequent processes.

Referring to FIG. 2G, a first gap-fill insulating layer 124 may be formed on the semiconductor substrate 110 including the trench 118. The first gap-fill insulating layer 124 may be a silicon oxide layer formed by CVD. The first gap-fill insulating layer 124 may be formed using a thermal decomposition CVD process using mono-silane (SiH₄) or tetra-ethoxy-silane (TEOS) as a reactant gas. When the trench 118 has a width of about 0.20 μm or less or has an aspect ratio of about 3 or more, a high-density plasma (HDP) CVD process or a thermal decomposition CVD process using ozone-TEOS (O₃-TEOS) as a reactant gas may be used to provide higher gap-fill capabilities.

Referring to FIG. 2H, the first gap-fill insulating layer 124 may be recessed to form a lower device isolation layer 124a having an upper surface lower than the surface of the semiconductor substrate 110. The forming of the lower device isolation layer 124a may be performed using a wet etching process. For example, the wet etching process may involve hydrofluoric acid (HF) having a high etch selectivity. Alternatively, the first gap-fill insulating layer 124 may be recessed by dry etching. Because the inner wall of the trench 118 may be protected by the liner nitride layer 122, damage to the semiconductor substrate 110 may be reduced or prevented.

It may be beneficial for the upper surface of the lower device isolation layer 124a to be recessed deeper, for example, than a channel of a MOS transistor (e.g., P-channel MOS transistor) that may be subsequently formed. However, when the lower device isolation layer 124a may be recessed relatively deeply, the area of the liner nitride layer 122 that may be subsequently thinned may increase, thus reducing the stress reduction effect of the liner nitride layer 122. Accordingly, it may be beneficial for the upper surface of the lower device isolation layer 124a to be as close as possible to the surface of the semiconductor substrate 110 to the extent that it may not be shallower than the channel of the MOS transistor.

Referring to FIG. 2I, the upper portion of the liner nitride layer 122 exposed by the forming of the lower device isolation layer 124a may be etched and thinned. The etching of the exposed liner nitride layer 122 may be performed with a wet etching process using an etchant containing phosphoric acid. Accordingly, the liner nitride layer 122 may be divided into a lower liner nitride layer 122a and an upper liner nitride layer 122b. The lower liner nitride layer 122a may be disposed between the lower device isolation layer 124a and the trench 118 and, thus, may not be etched. The exposed upper liner nitride layer 122b may be disposed above the lower device isolation layer 124a and may be etched. The upper liner nitride layer 122b may be about one-third as thick as the lower liner nitride layer 122a. The upper liner nitride layer 122b may have a thickness of about 40˜50 Å.

Referring to FIG. 2J, a second gap-fill insulating layer 126 may be formed on the lower device isolation layer 124a so as to fill the trench 118 and cover the semiconductor substrate 110. The second gap-fill insulating layer 126 may be a silicon oxide layer formed by CVD. For example, the forming of the second gap-fill insulating layer 126 may be performed with a thermal decomposition CVD process using mono-silane or TEOS as a reactant gas. When the trench 118 has a width of about 0.20 μm or less or has an aspect ratio of about 3 or more, an HDP CVD process or a thermal decomposition CVD process using ozone-TEOS as a reactant gas may be used to provide higher gap-fill capabilities.

Referring to FIG. 2K, the second gap-fill insulating layer 126 may be etched to form an upper device isolation layer 126a. The etching of the second gap-fill insulating layer 126 may involve planarizing the second gap-fill insulating layer 126 with a chemical mechanical polishing (CMP) process using the device isolation layer mask pattern 117a as an etch stop layer. Accordingly, a device isolation layer may have a two-layer structure including the lower device isolation layer 124a and the upper device isolation layer 126a. The device isolation layer may define an active region of the semiconductor substrate 110.

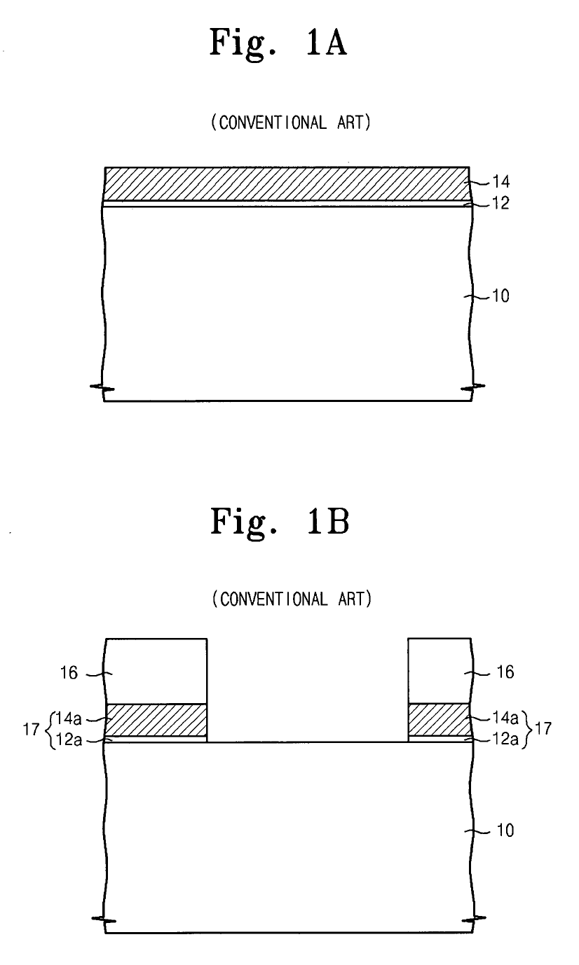

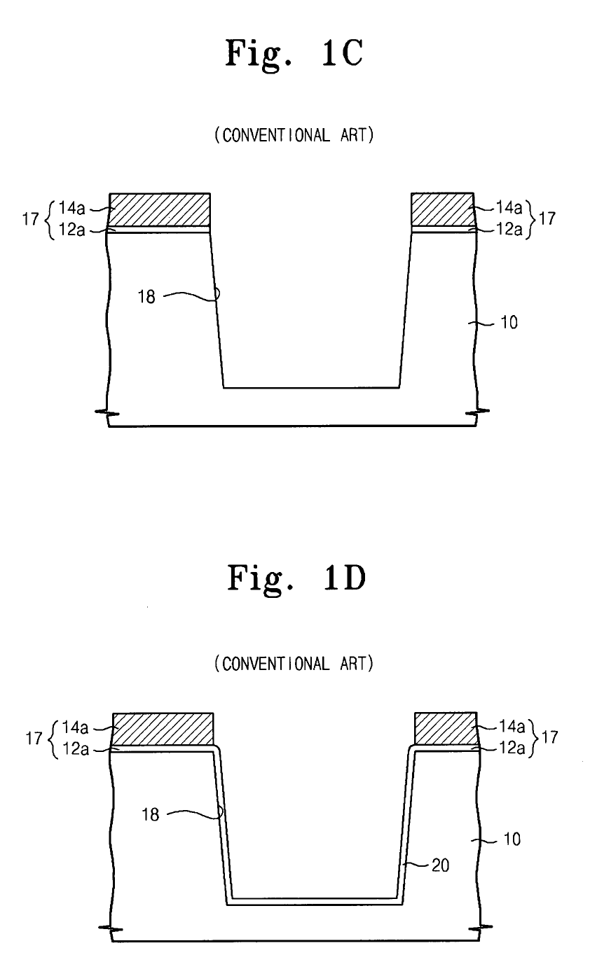

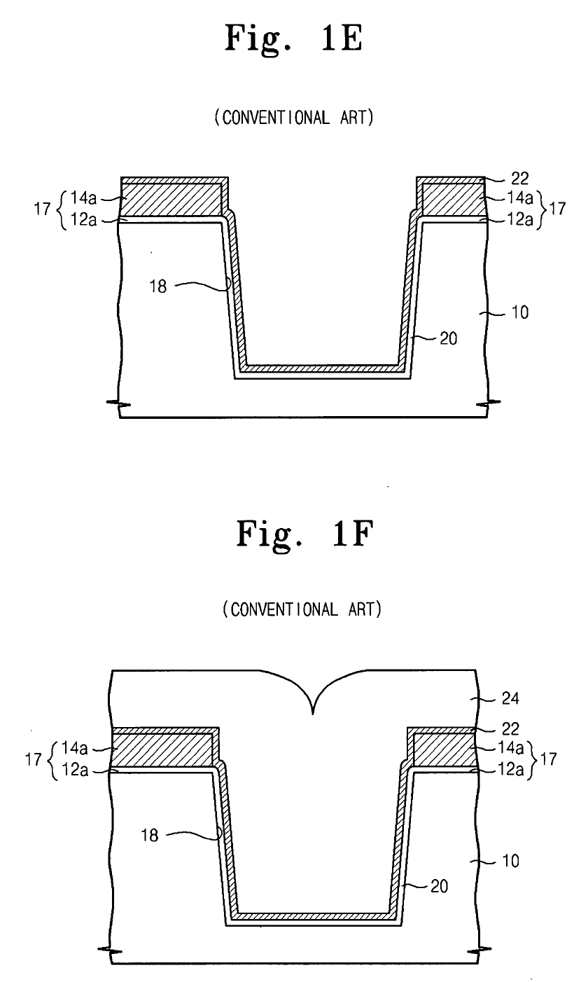

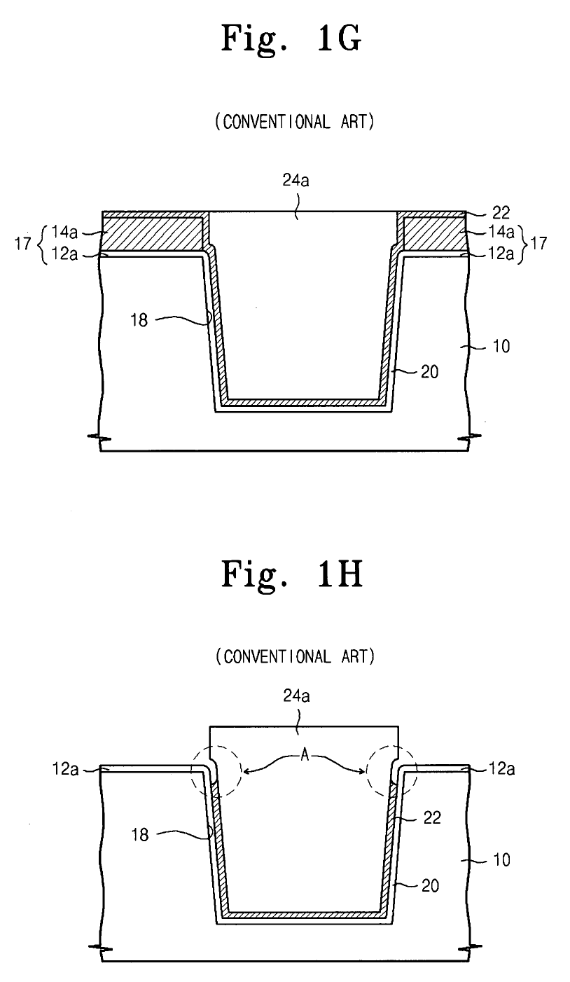

Referring to FIG. 2L, at least a portion of the device isolation layer mask pattern 117a may be removed. The removing of the device isolation layer mask pattern 117a may be performed using a wet etching process. The pad nitride layer pattern 114b may be removed with a wet etching process using an etchant containing phosphoric acid. Because of the relative thinness of the upper liner nitride layer 122b, infiltration of the etchant into the interface between the semiconductor substrate 110 and the upper device isolation layer 126a may be reduced or prevented. Accordingly, unlike the conventional art, the generation of a recessed portion (e.g., recessed portion A in FIG. 1H) between the active region and the device isolation layer may be reduced or prevented.

Following the formation of the device isolation layer, subsequent processes, including the implantation of channel ions and/or the formation of a gate insulating layer, a gate electrode, a first spacer, a lightly-doped drain, a second spacer, source/drain regions, a salicide, and/or a contact plug, may be performed to complete the fabrication of the semiconductor device.

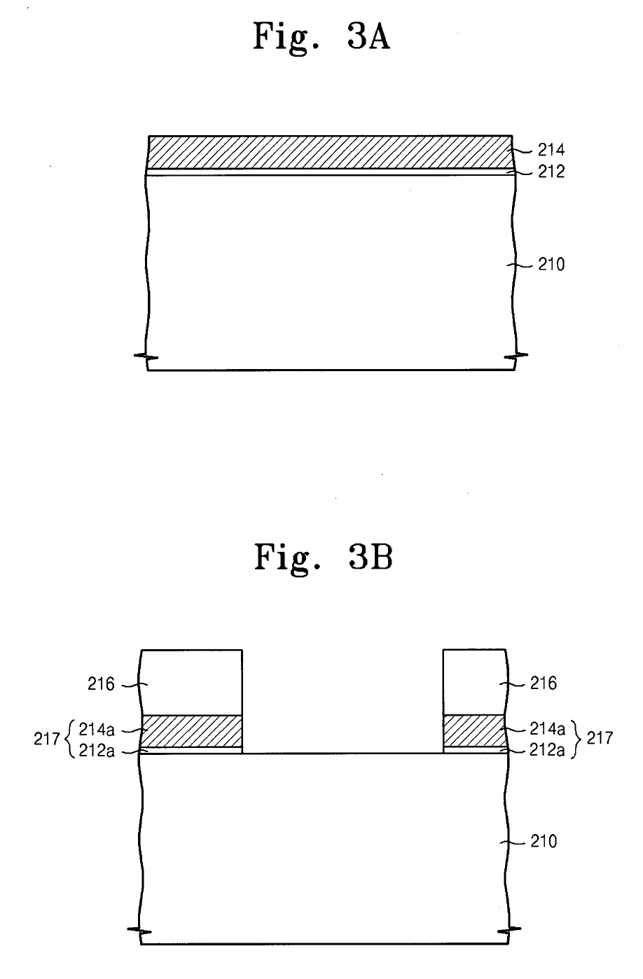

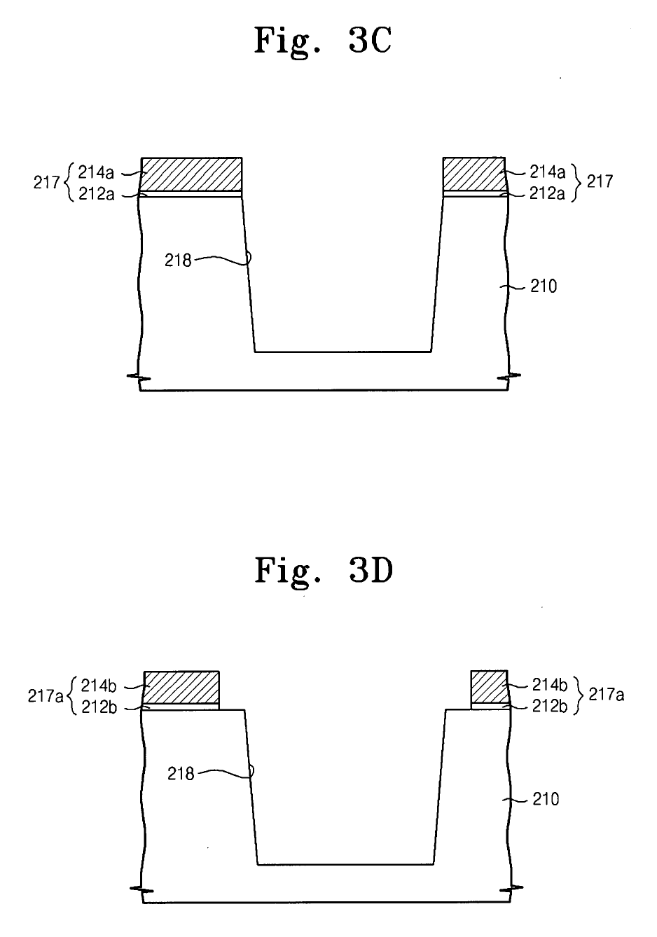

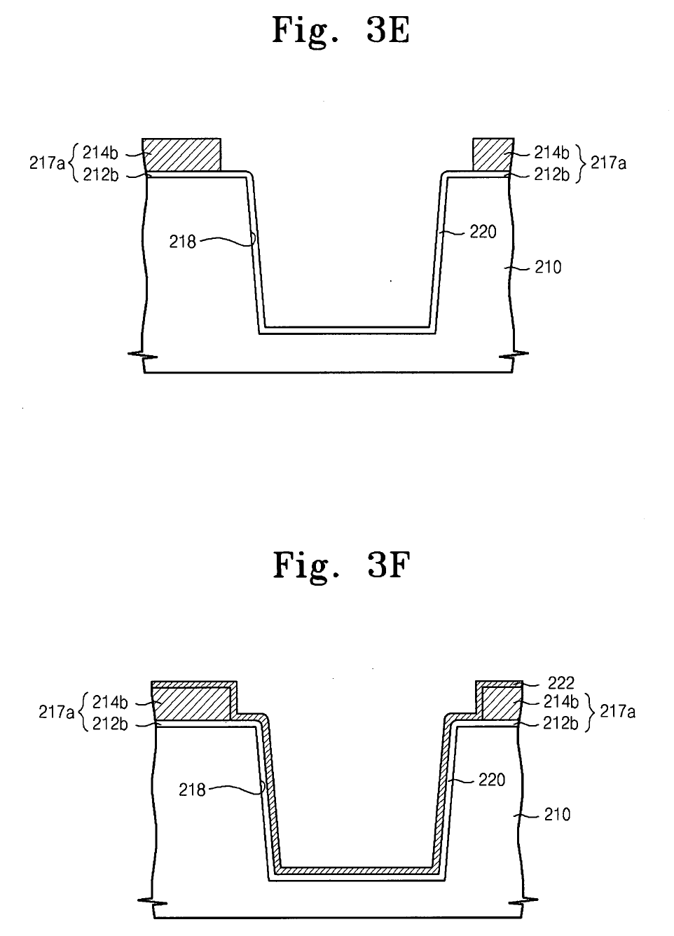

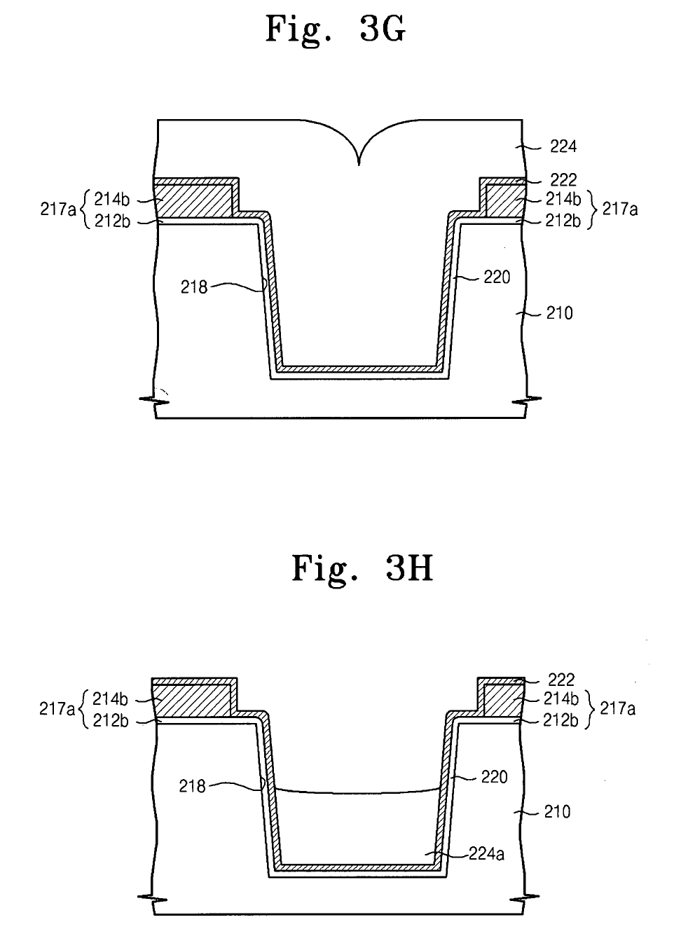

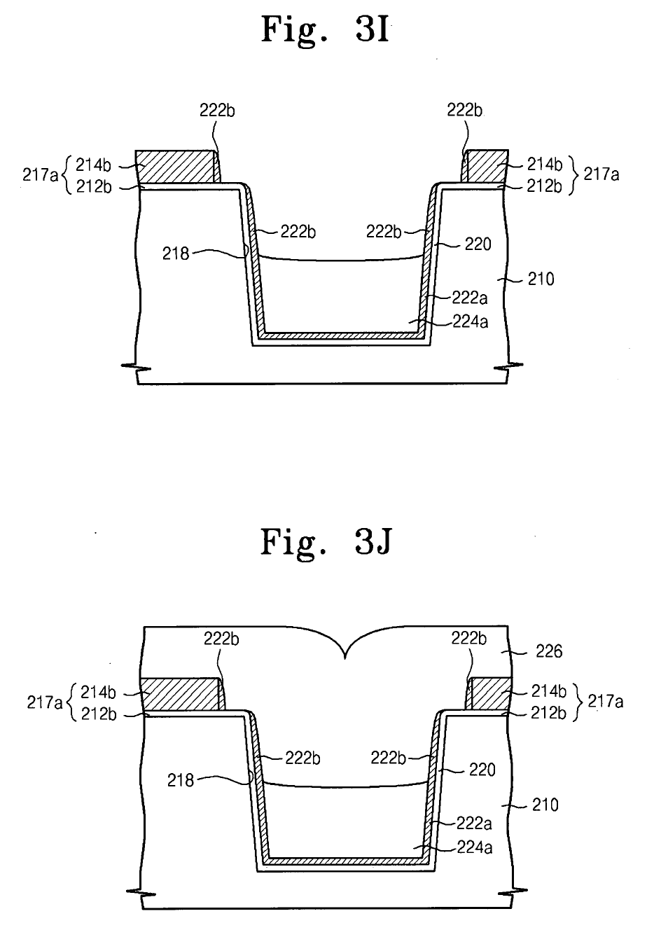

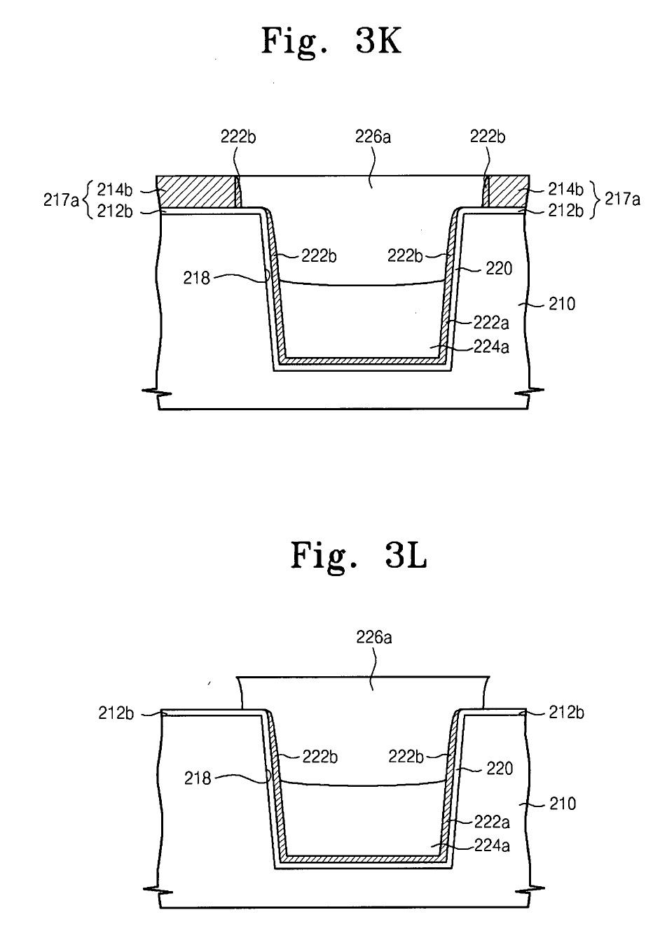

FIGS. 3A through 3L are sectional views illustrating a method for fabricating a semiconductor device according to additional example embodiments. Processes which may be similar to example embodiments previously described with reference to FIGS. 2A through 2L, may be applicable here as well and, thus, may not be described (or may be discussed only briefly) for purposes of conciseness. Referring to FIGS. 3A through 3H, a pad oxide layer 212 and a pad nitride layer 214 may be formed on a semiconductor substrate 210. A photoresist pattern 216 may be formed on the pad nitride layer 214. Using the photoresist pattern 216 as an etch mask, the pad nitride layer 214 and the pad oxide layer 212 may be etched to form a trench mask pattern 217 (including a pad nitride layer pattern 214a and a pad oxide layer pattern 212a).

The photoresist pattern 216 may be removed, and the semiconductor substrate 210 may be etched using the trench mask pattern 217 as an etch mask to form a trench 218. Alternatively, the photoresist pattern 216 may be used as an etch mask to sequentially etch the pad nitride layer 214, the pad oxide layer 212, and the semiconductor substrate 210 to form the trench 218.

A portion of the trench mask pattern 217 surrounding the trench 218 may be further etched to form a device isolation layer mask pattern 217a (including a pad nitride layer pattern 214b and a pad oxide layer pattern 212b) having an opening exposing the surface of the semiconductor substrate 210 surrounding the trench 218. A liner oxide layer 220 may be formed on the inner wall of the trench 218, and a liner nitride layer 222 may be formed on the semiconductor substrate 210 including the inner wall of the trench 218. A first gap-fill insulating layer 224 may be formed on the semiconductor substrate 210 including the trench 218. The first gap-fill insulating layer 224 may be recessed to form a lower device isolation layer 224a having an upper surface lower than the surface of the semiconductor substrate 210 while exposing the upper portion of the liner nitride layer 222.

Referring to FIG. 31, the exposed upper portion of the liner nitride layer 222 may be etched to form a spacer-shaped upper liner nitride layer 222b. The etching of the exposed liner nitride layer 222 may be performed using an anisotropic dry etching process. Accordingly, the liner nitride layer 222 may be divided into a lower liner nitride layer 222a and the spacer-shaped upper liner nitride layer 222b. The lower liner nitride layer 222a may be disposed between the lower device isolation layer 224a and the trench 218 and, thus, may not be etched. The spacer-shaped upper liner nitride layer 222b may be disposed above the lower device isolation layer 224a and may be exposed and etched. The spacer-shaped upper liner nitride layer 222b may also be disposed on the exposed sidewalls of the device isolation layer mask pattern 217a.

Referring to FIG. 3J, a second gap-fill insulating layer 226 may be formed on the lower device isolation layer 224a so as to fill the trench 218 and cover the semiconductor substrate 210. The second gap-fill insulating layer 226 may be a silicon oxide layer formed by CVD. For example, the forming of the second gap-fill insulating layer 226 may be performed with a thermal decomposition CVD process using mono-silane or TEOS as a reactant gas. When the trench 218 has a width of about 0.20 μm or less or has an aspect ratio of about 3 or more, an HDP CVD process or a thermal decomposition CVD process using ozone-TEOS as a reactant gas may be used to provide higher gap-fill capabilities.

Alternatively, the process of forming of the spacer-shaped upper liner nitride layer 222b described above with reference to FIG. 31 may be omitted, and the second gap-fill insulating layer 226 may be formed using an HDP CVD process. With the HDP CVD process, a deposition/etch process cycle may be repeatedly performed on the lower device isolation layer 224a so as to form the second gap-fill insulating layer 226 covering the semiconductor substrate 210 and filling the trench 218. Because of the plurality of deposition/etch process cycles performed, the exposed upper portion of the liner nitride layer 222 may be gradually etched so as to be spacer-shaped. Accordingly, the liner nitride layer 222 may be divided into a lower liner nitride layer 222a and a spacer-shaped upper nitride layer 222b. The lower liner nitride layer 222a may be disposed between the lower device isolation layer 224a and the trench 218, while the spacer-shaped upper liner nitride layer 222b may be disposed between the second gap-fill insulating layer 226 and the trench 218. The forming of the second gap-fill insulating layer 226 and the forming of the spacer-shaped upper liner nitride layer 222b may be performed in situ.

Referring to FIGS. 3K and 3L, the second gap-fill insulating layer 226 may be etched to form an upper device isolation layer 226a. Accordingly, a device isolation layer may have a two-layer structure including the lower device isolation layer 224a and the upper device isolation layer 226a. The device isolation layer may define an active region of the semiconductor substrate 210.

At least a portion of the device isolation layer mask pattern 217a may be removed. The removing of the device isolation layer mask pattern 217a may be performed using a wet etching process. For example, the pad nitride layer pattern 214b may be removed with a wet etching process using an etchant containing phosphoric acid. The upper liner nitride layer 222b disposed on the sidewall of the device isolation layer mask pattern 217a may also be removed. Because the spacer-shaped upper liner nitride layer 222b may be disposed between the trench 218 and the upper device isolation layer 226a, the infiltration of the etchant into the interface between the device isolation layer and the active region may be reduced or prevented. Accordingly, unlike the conventional art, the generation of a recessed portion (e.g., recessed portion A in FIG. 1H) between the active region and the device isolation layer may be reduced or prevented.

Following the formation of the device isolation layer, subsequent processes, including the implantation of channel ions and/or the formation of a gate insulating layer, a gate electrode, a first spacer, a lightly-doped drain, a second spacer, source/drain regions, a salicide, and/or a contact plug, may be performed to complete the fabrication of the semiconductor device.

Accordingly, a relatively high-quality semiconductor device may be fabricated using a simplified process according to example embodiments. Additionally, decreased reliability of the semiconductor device due to layer contamination may be reduced or prevented by using the above simplified method according to example embodiments. For example, the liner nitride layer may capture electrons adversely affecting a P-channel MOS transistor so as to reduce or prevent a shift in threshold voltage.

While example embodiments have been disclosed herein, it should be understood that other variations may be possible. Such variations are not to be regarded as a departure from the spirit and scope of example embodiments of the present invention, and all such modifications as would be obvious to one skilled in the art are intended to be included within the scope of the following claims.

What is claimed is:

1. A method of fabricating a semiconductor device, comprising:
providing a mask pattern on a substrate, the mask pattern having an opening that exposes a region of the substrate;
etching the exposed region of the substrate to form a trench;
etching a portion of the mask pattern surrounding the trench so as to form a mask pattern opening exposing a surface of the substrate surrounding the trench;
forming a liner nitride layer on the substrate including the trench;
etching the liner nitride layer such that an upper portion of the liner nitride layer is thinner than a lower portion of the liner nitride layer, and forming an isolation layer on the substrate so as to fill the trench and the mask pattern opening; and
removing at least a portion of the mask pattern.

2. The method of claim 1, wherein etching the exposed region of the substrate to form a trench includes an anisotropic dry etching process.

3. The method of claim 1, wherein etching the portion of the mask pattern surrounding the trench includes a pull-back etching process.

4. The method of claim 1, wherein etching the liner nitride layer includes a wet etching process.

5. The method of claim 1, wherein etching the liner nitride layer includes an anisotropic dry etching process.

6. The method of claim 1, further comprising:
forming a liner oxide layer on the substrate prior to forming the liner nitride layer.

7. The method of claim 1, wherein forming the isolation layer comprises:
forming a lower isolation layer in the trench such that an upper surface of the lower isolation layer is lower than the surface of the substrate and such that the upper portion of the liner nitride layer is exposed; and
forming an upper isolation layer on the lower isolation layer so as to fill the trench and the mask pattern opening.

8. The method of claim 7, wherein forming the lower isolation layer comprises:
forming a first gap-fill insulating layer so as to fill the trench; and
etching the first gap-fill insulating layer so as to form the lower isolation layer having an upper surface lower than the surface of the substrate.

9. The method of claim 7, wherein forming the upper isolation layer comprises:
forming a second gap-fill insulating layer so as to cover the substrate, including filling the trench and the mask pattern opening; and
planarizing the second gap-fill insulating layer using the mask pattern as an etch stop layer so as to form the upper isolation layer.

10. The method of claim 7, wherein forming the upper isolation layer comprises:
performing a plurality of cycles of a deposition/etch process on the lower isolation layer to form a second gap-fill insulating layer covering the substrate and filling the trench and the mask pattern opening, wherein the exposed upper portion of the liner nitride layer is gradually thinned with the forming of the second gap-fill insulating layer; and
planarizing the second gap-fill insulating layer using the mask pattern as an etch stop layer so as to form the upper isolation layer.

11. A semiconductor device comprising:
a substrate having a trench;
an isolation layer in the trench and on at least a portion of a surface of the substrate surrounding the trench; and
a liner nitride layer between the substrate and the isolation layer, the liner nitride layer having an upper portion and a lower portion, wherein the upper portion is thinner than the lower portion.

12. The semiconductor device of claim 11, wherein the trench has a depth of about 3500-4500 Å.

13. The semiconductor device of claim 11, wherein the isolation layer comprises:
a lower isolation layer, wherein the lower portion of the liner nitride layer is between the lower isolation layer and the substrate; and
an upper isolation layer, wherein the upper portion of the liner nitride layer is between the upper isolation layer and the substrate.

14. The semiconductor device of claim 11, wherein the isolation layer includes silicon oxide.

15. The semiconductor device of claim 11, wherein the upper portion of the liner nitride layer is about one-third as thick as the lower portion of the liner nitride layer.

16. The semiconductor device of claim 15, wherein the upper portion of the liner nitride layer has a thickness of about 40˜50 Å.

17. The semiconductor device of claim 11, wherein the liner nitride layer tapers in thickness from the lower portion to the upper portion.

18. The semiconductor device of claim 17, wherein the upper portion of the liner nitride layer is spacer-shaped.

19. The semiconductor device of claim 11, wherein the liner nitride layer includes silicon nitride.

20. The semiconductor device of claim 11, further comprising a liner oxide layer between the liner nitride layer and the substrate.
